(19) United States
(12) Patent Application Publication
(10) Pub. No.: US 2025/0046712 A1
(43) Pub. Date: Feb. 6, 2025

(54) WIRING SUBSTRATE AND SEMICONDUCTOR DEVICE

(71) Applicant: SHINKO ELECTRIC INDUSTRIES CO., LTD., Nagano-shi (JP)

(72) Inventor: Yoshiki AKIYAMA, Matsumoto-shi (JP)

(21) Appl. No.: 18/786,852

(22) Filed: Jul. 29, 2024

(30) Foreign Application Priority Data
Aug. 2, 2023 (JP) 2023-126070

(51) Int. Cl. H01L 23/528; H01L 23/498; H01L 23/522; H01L 23/532

(52) U.S. Cl. CPC H01L 23/5283; H01L 23/49816; H01L 23/5226; H01L 23/53295

(57) ABSTRACT

A wiring substrate includes a first wiring layer, a first insulating layer covering the first wiring layer, a second wiring layer formed on the first insulating layer and connected to the first wiring layer, a second insulating layer formed on the first insulating layer, and a third wiring layer formed on the second insulating layer and connected to the second wiring layer. The second wiring layer includes a first connection pad connectable to a first electronic component, and a wiring pattern connected to the third wiring layer. The second insulating layer includes an open portion extending through the second insulating layer in a thickness-wise direction and exposing the first connection pad and part of the first insulating layer. The third wiring layer includes a second connection pad connectable to a second electronic component. The first wiring layer includes wiring that electrically connects the first and second connection pads.

### CROSS-REFERENCE TO RELATED APPLICATIONS

This application is based upon and claims the benefit of priority from prior Japanese Patent Application No. 2023-126070, filed on Aug. 2, 2023, the entire contents of which are incorporated herein by reference.

### BACKGROUND

### 1. Field

This disclosure relates to a wiring substrate, a semiconductor device, and a method for manufacturing a wiring substrate.

### 2. Description of Related Art

Japanese Laid-Open Patent Publication No. 2020-107681 describes a semiconductor device including a wiring substrate on which a plurality of electronic components are mounted. In this type of semiconductor device, an underfill material is added to a gap between a wiring substrate and an electronic component to protect the portion where the wiring substrate is connected to the electronic component from external stress and the like so that the connection reliability is improved.

### SUMMARY

When a number of electronic components are densely mounted on the wiring substrate, the underfill material may flow into a gap between the wiring substrate and an unintended one of electronic components. Accordingly, the amount of the underfill material between the wiring substrate and some of the electronic components may become insufficient or excessive. In this case, the unevenly added underfill material may lower the connection reliability between the wiring substrate and the electronic components.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a wiring substrate includes a first wiring layer, a first insulating layer, a second wiring layer, a second insulating layer, and a third wiring layer. The first insulating layer covers the first wiring layer. The second wiring layer is formed on an upper surface of the first insulating layer and is electrically connected to the first wiring layer. The second insulating layer is formed on the upper surface of the first insulating layer. The third wiring layer is formed on an upper surface of the second insulating layer and is electrically connected to the second wiring layer. The second wiring layer includes a first connection pad and a wiring pattern. The first connection pad is configured to be connected to a first electronic component. The wiring pattern is electrically connected to the third wiring layer. The second insulating layer includes an open portion extending through the second insulating layer in a thickness-wise direction. The open portion exposes the first connection pad and part of the upper surface of the first insulating layer. The third wiring layer includes a second connection pad configured to be connected to a second electronic component that differs from the first electronic component. The first wiring layer includes wiring that electrically connects the first connection pad and the second connection pad.

Other features and aspects will be apparent from the following detailed description, the drawings, and the claims.

### BRIEF DESCRIPTION OF THE DRAWINGS

FIG. 1 is a schematic cross-sectional view of a semiconductor device in accordance with an embodiment.

FIGS. 2, 3, 4, 5, 6, 7, 8, 9, 10, 11, 12, 13, 14, 15, 16, 17, 18, 19, and 20 are schematic cross-sectional views illustrating a method for manufacturing the semiconductor device illustrated in FIG. 1.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

An embodiment will now be described with reference to the drawings.

In the accompanying drawings, elements are illustrated for simplicity and clarity and have not necessarily been drawn to scale. To facilitate understanding, hatching lines may not be shown or be replaced by shadings in the cross-sectional views.

### Configuration of Semiconductor Device 10

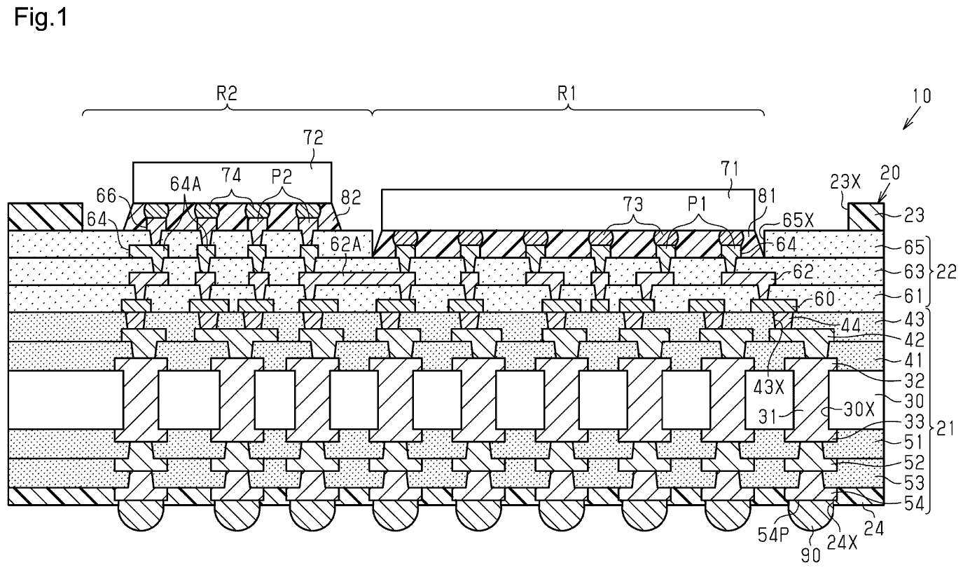

As illustrated in FIG. 1, a semiconductor device 10 includes a wiring substrate 20, electronic components, underfill materials 81 and 82, and external connection terminals 90. In the present embodiment, the electronic components include a first electronic component 71 and a second electronic component 72.

### Structure of Wiring Substrate 20

The wiring substrate 20 includes wiring structures 21 and 22 and solder resist layers 23 and 24. The wiring structure 22 is formed on an upper surface of the wiring structure 21. The solder resist layer 23 is formed on an upper surface of the wiring structure 22. The solder resist layer 24 is formed on a lower surface of the wiring structure 21. For example, the wiring structure 21 is a low-density wiring layer in which a wiring layer is formed at a wiring density lower than the wiring structure 22. For example, the wiring structure 22 is a high-density wiring layer in which a wiring layer is formed at a wiring density higher than the wiring structure 21. The wiring substrate 20 may have any planar shape and any size. The planar shape of the wiring substrate 20 may be, for example, a quadrangle that is approximately 20 mm×20 mm to 40 mm×40 mm.

### Structure of Wiring Structure 21

The wiring structure 21 includes a core substrate 30. The core substrate 30 is located, for example, at a central part of the wiring structure 21 in a thickness-wise direction. The material of the core substrate 30 may be, for example, a glass epoxy substrate obtained by impregnating a glass cloth (glass woven cloth), which is a reinforcement material, with a thermosetting insulating resin, which includes an epoxy resin as a main component, and curing the resin. The reinforcement material is not limited to a glass cloth and may be, for example, a glass non-woven cloth, an aramid woven cloth, an aramid non-woven cloth, a liquid crystal polymer (LCP) woven cloth, or an LCP non-woven cloth. The thermosetting insulating resin is not limited to epoxy resin and may be, for example, a resin material such as polyimide resin or cyanate resin. The core substrate 30 may contain, for example, a filler such as silica (SiO₂) or alumina (Al₂O₃). The core substrate 30 may have a thickness of, for example, approximately 800 μm to 2000 μm.

The core substrate 30 includes a through hole 30X at given locations (nine locations in FIG. 1). The through holes 30X extend through the core substrate 30 in the thickness-wise direction. A through-electrode 31 is formed in each through hole 30X and extends through the core substrate 30 in the thickness-wise direction. The through holes 30X are, for example, filled with the through-electrodes 31. The material of the through-electrode 31 may be, for example, copper (Cu) or a copper alloy.

A wiring layer 32 is formed on an upper surface of the core substrate 30, and a wiring layer 33 is formed on a lower surface of the core substrate 30. The wiring layers 32 and 33 are electrically connected to each other by the through-electrodes 31. The material of the wiring layers 32 and 33 may be, for example, copper or a copper alloy. The wiring layers 32 and 33 may each have a thickness of, for example, approximately 15 μm to 35 μm. The wiring layers 32 and 33 may each have a line-and-space (L/S) of, for example, approximately 20 μm/20 μm. The line-and-space indicates a wiring width (L) and an interval (S) between adjacent wiring parts.

An insulating layer 41, a wiring layer 42, an insulating layer 43, and via wiring 44 are sequentially stacked on the upper surface of the core substrate 30. The material of the insulating layers 41 and 43 may be, for example, a non-photosensitive insulating resin including a thermosetting resin, such as an epoxy resin or a polyimide resin, as a main component. The insulating layers 41 and 43 may contain, for example, a filler such as silica or alumina. The material of the wiring layer 42 and the via wiring 44 may be, for example, copper or a copper alloy. The insulating layers 41 and 43 may each have a thickness of, for example, approximately 20 μm to 45 μm. The wiring layer 42 may have a thickness of, for example, approximately 15 μm to 35 μm. The wiring layer 42 may have a line-and-space (L/S) of approximately 20 μm/20 μm.

The insulating layer 41 is formed on the upper surface of the core substrate 30 and covers the wiring layer 32. The wiring layer 42 is formed on an upper surface of the insulating layer 41. For example, the wiring layer 42 is formed integrally with via wiring extending through the insulating layer 41 in the thickness-wise direction and is electrically connected to the wiring layer 32 by the via wiring.

The insulating layer 43 is the uppermost insulating layer of the wiring structure 21. The insulating layer 43 is formed on the upper surface of the insulating layer 41 and covers the wiring layer 42. The insulating layer 43 includes through holes 43X extending through the insulating layer 43 in the thickness-wise direction and exposing parts of an upper surface of the wiring layer 42.

An upper surface of the insulating layer 43 is a smooth surface (low roughness surface) having relatively few irregularities. The upper surface of the insulating layer 43 is, for example, a polished surface. The upper surface of the insulating layer 43 is set to have a roughness Ra of, for example, approximately 15 nm to 40 nm. The surface roughness Ra is a type of numerical value that represents surface roughness and is referred to as arithmetic mean roughness. The surface roughness Ra is obtained by measuring absolute values of various heights from a surface, which serves as the average line, within a measurement region and arithmetically averaging these values.

The via wiring 44 is formed in each through hole 43X. The via wiring 44 electrically connects the wiring layer 42 and a wiring layer 60 formed on the upper surface of the insulating layer 43. The through hole 43X is filled with the via wiring 44. The via wiring 44 is shaped in correspondence with the through hole 43X. The via wiring 44 is tapered such that its diameter decreases from the upper side (side close to wiring layer 60) toward the lower side (side close to wiring layer 42) in FIG. 1. The via wiring 44 has the form of, for example, a reversed truncated cone so that its upper end surface has a larger diameter than its lower end surface. The upper end surface of the via wiring 44 is exposed from the insulating layer 43. The upper end surface of the via wiring 44 is, for example, flush with the upper surface of the insulating layer 43. The upper end surface of the via wiring 44 is, for example, a polished surface. The diameter of the upper end surface of the via wiring 44 may be, for example, approximately 60 μm to 70 μm.

An insulating layer 51, a wiring layer 52, an insulating layer 53, and a wiring layer 54 are sequentially stacked on the lower surface of the core substrate 30. The material of the insulating layers 51 and 53 may be, for example, a non-photosensitive insulating resin including a thermosetting resin, such as an epoxy resin or a polyimide resin, as a main component. The insulating layers 51 and 53 may contain, for example, a filler such as silica or alumina. The material of the wiring layers 52 and 54 may be, for example, copper or a copper alloy. The insulating layers 51 and 53 may each have a thickness of, for example, approximately 20 μm to 45 μm. The wiring layers 52 and 54 may each have a thickness of, for example, approximately 15 μm to 35 μm. The wiring layers 52 and 54 may each have a line-and-space (L/S) of approximately 20 μm/20 μm.

The insulating layer 51 is formed on the lower surface of the core substrate 30 and covers the wiring layer 33. The wiring layer 52 is formed on a lower surface of the insulating layer 51. For example, the wiring layer 52 is formed integrally with via wiring extending through the insulating layer 51 in the thickness-wise direction and is electrically connected to the wiring layer 33 by the via wiring. The insulating layer 53 is formed on the lower surface of the insulating layer 51 and covers the wiring layer 52. The insulating layer 53 is the lowermost insulating layer of the wiring structure 21. The wiring layer 54 is formed on a lower surface of the insulating layer 53. The wiring layer 54 is the lowermost wiring layer of the wiring structure 21. For example, the wiring layer 54 is formed integrally with via wiring extending through the insulating layer 53 in the thickness-wise direction and is electrically connected to the wiring layer 52 by the via wiring.

### Structure of Solder Resist Layer 24

The solder resist layer 24 is the outermost insulating layer (lowermost insulating layer) of the wiring substrate 20. The solder resist layer 24 is formed on the lower surface of the wiring structure 21. In the example illustrated in FIG. 1, the solder resist layer 24 is formed on the lower surface of the insulating layer 53 of the wiring structure 21 and covers the wiring layer 54. The material of the solder resist layer 24 may be, for example, an insulating resin including a photosensitive resin, such as a phenol resin or a polyimide resin, as a main component. The solder resist layer 24 may contain, for example, a filler such as silica or alumina.

The solder resist layer 24 includes openings 24X that expose parts of the wiring layer 54 as external connection pads 54P. The external connection pads 54P are connected to the external connection terminals 90 used when mounting the wiring substrate 20 on a mounting substrate such as a motherboard.

A surface-processed layer is formed, if necessary, on a lower surface of the wiring layer 54 exposed at the bottom of each opening 24X. Examples of the surface-processed layer include a gold (Au) layer, a nickel (Ni) layer/Au layer (metal layer in which Ni layer serves as bottom layer, and Au layer is formed on Ni layer), an Ni layer/palladium (Pd) layer/Au layer (metal layer in which Ni layer serves as bottom layer, and Ni layer and Pd layer are sequentially formed on Au layer), or the like. Further examples of the surface-processed layer include an Ni layer/Pd layer (metal layer in which Ni layer serves as bottom layer, and Pd layer is formed on Ni layer), a Pd layer/Au layer (metal layer in which Pd layer serves as bottom layer, and Au layer is formed on Pd layer), or the like. An Au layer is a metal layer formed from Au or an Au alloy, an Ni layer is a metal layer formed from Ni or an Ni alloy, and a Pd layer is a metal layer formed from Pd or a Pd alloy. An Au layer, an Ni layer, and a Pd layer may each be, for example, a metal layer formed by an electroless plating process (electroless plating layer) or a metal layer formed by an electrolytic plating process (electrolytic plating layer). Alternatively, the surface-processed layer may be an organic solderability preservative (OPS) film formed by performing an anti-oxidation process, such as an OSP process, on the lower surface of the wiring layer 54 exposed from each opening 24X. The OSP film may be an organic coating of an azole compound, an imidazole compound, or the like. When a surface-processed layer is formed on the lower surface of the wiring layer 54, the surface-processed layer will act as the external connection pad 54P. The wiring layer 54 exposed from the opening 24X (or surface-processed layer, if surface-processed layer is formed on wiring layer 54) may be used as an external connection terminal.

The external connection pad 54P and the opening 24X may have any planar shape and any size. The planar shapes of the external connection pad 54P and the opening 24X may each be, for example, a circle having a diameter of approximately 100 μm to 300 μm.

### Structure of Wiring Structure 22

The wiring structure 22 has a structure in which the wiring layer 60, an insulating layer 61, a wiring layer 62, an insulating layer 63, a wiring layer 64, an insulating layer 65, and a wiring layer 66 are sequentially stacked on the upper surface of the insulating layer 43. The wiring structure 22 includes a first connection pad P1 configured to be connected to the first electronic component 71, and a second connection pad P2 configured to be connected to the second electronic component 72. The first connection pad P1 and the second connection pad P2 are arranged on different planes.

The material of the wiring layers 60, 62, 64, and 66 may be, for example, copper or a copper alloy. The material of the insulating layers 61, 63, and 65, may be, for example, a photosensitive insulating resin including a phenol resin, a polyimide resin, or the like, as a main component. The insulating layers 61, 63, and 65 may contain, for example, a filler such as silica or alumina.

Each of the wiring layers 60, 62, 64, and 66 is thinner than each of the wiring layers 32, 33, 42, 52, and 54 of the wiring structure 21. The wiring layers 60 and 62 may each have a thickness of, for example, approximately 1 μm to 3 μm. The wiring layers 64 and 66 may each have a thickness of, for example, approximately 1 μm to 15 μm. The wiring layers 60, 62, 64, and 66 may each have a line-and-space (L/S) of approximately 2 μm/2 μm. Each of the insulating layers 61, 63, and 65 is thinner than each of the insulating layers 41, 43, 51, and 53 of the wiring structure 21. The insulating layers 61, 63, and 65 may each have a thickness of, for example, approximately 5 μm to 10 μm.

The wiring layer 60 is formed on the upper surface of the insulating layer 43 and is connected to the upper end surface of the via wiring 44. Part of the lower surface of the wiring layer 60 is in contact with the upper end surface of the via wiring 44 so that the wiring layer 60 is electrically connected to the via wiring 44. Although the wiring layer 60 is electrically connected to the via wiring 44, the wiring layer 60 and the via wiring 44 are not integrated with each other. The wiring layer 60 includes, for example, a seed layer formed on the upper end surface of the via wiring 44 and a metal layer formed on the seed layer.

The insulating layer 61 is formed on the upper surface of the insulating layer 43 and covers the wiring layer 60. The wiring layer 62 is formed on an upper surface of the insulating layer 61. For example, the wiring layer 62 is formed integrally with via wiring extending through the insulating layer 61 in the thickness-wise direction and is electrically connected to the wiring layer 60 by the via wiring. The wiring layer 62 includes wiring 62A that electrically connects the first connection pad P1 and the second connection pad P2. The insulating layer 63 is formed on the upper surface of the insulating layer 61 and covers the wiring layer 62.

The wiring layer 64 is formed on an upper surface of the insulating layer 63. For example, the wiring layer 64 is formed integrally with via wiring extending through the insulating layer 63 in the thickness-wise direction and is electrically connected to the wiring layer 62 by the via wiring.

The wiring layer 64 includes one or more first connection pads P1 configured to be connected to the first electronic component 71, and one or more wiring patterns 64A. The first connection pads P1 and the wiring patterns 64A are formed on the same plane. In the example illustrated in FIG. 1, the first connection pads P1 and the wiring patterns 64A are both formed on the upper surface of the insulating layer 63. That is, the first connection pads P1 and the wiring patterns 64A are coplanar with each other on the upper surface of the insulating layer 63.

The first connection pads P1 are arranged in a first mounting region R1 in which the first electronic component 71 is mounted. Each first connection pad P1 includes an upper surface and a side surface that are exposed from the insulating layer 65. The first connection pad P1 projects upward from the upper surface of the insulating layer 63 that is exposed from the insulating layer 65. The first connection pad P1 may have any planar shape and any size. The planar shape of the first connection pad P1 may be, for example, a circle having a diameter of approximately 20 μm to 30 μm. The distance between the consecutive first connection pads P1 may be, for example, approximately 40 μm to 60 μm. The first connection pads P1 act as electronic component mounting pads for electrical connection to the first electronic component 71.

A surface-processed layer may be formed, if necessary, on the surfaces (upper and side surfaces or only upper surface) of the first connection pads P1. Examples of the surface-processed layer include an OSP film or a metal layer, such as an Au layer, an Ni layer/Au layer, an Ni layer/Pd layer/Au layer, an Ni layer/Pd layer, or a Pd layer/Au layer.

Each wiring pattern 64A includes an upper surface and a side surface that are covered with the insulating layer 65. The wiring patterns 64A are arranged outside the first mounting region R1. The wiring patterns 64A are arranged so as not to overlap the first mounting region R1 in plan view. The first connection pad P1 and the wiring pattern 64A may have the same thickness or different thicknesses. The first connection pad P1 may be, for example, thicker than the wiring pattern 64A. In this case, the thickness of the first connection pad P1 may be approximately 10 μm to 15 μm, and the thickness of the wiring pattern 64A may be approximately 1 μm to 3 μm.

The insulating layer 65 is formed on the upper surface of the insulating layer 63 and covers the wiring patterns 64A of the wiring layer 64. The insulating layer 65 includes an open portion 65X extending through the insulating layer 65 in the thickness-wise direction and exposing the first connection pads P1 and part of the upper surface of the insulating layer 63. The open portion 65X exposes the entire upper surface and the entire side surface of each first connection pad P1. In plan view, the open portion 65X overlaps the first mounting region R1, in which the first electronic component 71 is mounted. The open portion 65X may have a planar shape that corresponds to a planar shape of the first mounting region R1, for example, rectangular. The open portion 65X exposes all of the first connection pads P1 arranged in the first mounting region R1 and the entire upper surface of the insulating layer 63 in the first mounting region R1. In other words, the insulating layer 65 surrounds the first mounting region R1. The open portion 65X is a recess that is recessed from the upper surface of the insulating layer 65 and has a bottom surface defined by the upper surface of the insulating layer 63 so that the recess exposes the first connection pad P1 while covering the wiring pattern 64A with the insulating layer. The upper surface of the insulating layer 63 exposed from the open portion 65X is flat. The upper surface of the insulating layer 63 exposed from the open portion 65X has, for example, the same flatness as the upper surface of the insulating layer 63 covered by the insulating layer 65.

The wiring structure 22 includes a step formed by an upper surface of the insulating layer 65, an inner wall surface of the open portion 65X, and the upper surface of the insulating layer 63 exposed from the open portion 65X.

The wiring layer 66 is formed on the upper surface of the insulating layer 65. For example, the wiring layer 66 is formed integrally with via wiring extending through the insulating layer 65 in the thickness-wise direction and is electrically connected to the wiring layer 64 by the via wiring. The wiring layer 66 includes the second connection pads P2 connected to the second electronic component 72. The second connection pads P2 are arranged in a second mounting region R2 in which the second electronic component 72 is mounted. The second connection pads P2 are arranged so as not to overlap the first mounting region R1 in plan view. In the example illustrated in FIG. 1, the second connection pads P2 are arranged in an outer peripheral region outside the first mounting region R1 in plan view. The second connection pads P2 are located upward from the first connection pads P1. The second connection pads P2 are, for example, electrically connected to the wiring patterns 64A by the via wiring extending through the insulating layer 65 in the thickness-wise direction. The second connection pads P2 project upward from the upper surface of the insulating layer 65. The second connection pad P2 may have any planar shape and any size. The planar shape of the second connection pad P2 may be, for example, a circle having a diameter of approximately 20 μm to 30 μm. The distance between the consecutive second connection pads P2 may be, for example, approximately 40 μm to 60 μm. The second connection pad P2 may have a thickness of, for example, approximately 10 μm to 15 μm. The second connection pads P2 act as electronic component mounting pads for electrical connection to the second electronic component 72.

A surface-processed layer may be formed, if necessary, on the surfaces (upper and side surfaces or only upper surface) of the second connection pads P2. Examples of the surface-processed layer include an OSP film or a metal layer, such as an Au layer, an Ni layer/Au layer, an Ni layer/Pd layer/Au layer, an Ni layer/Pd layer, or a Pd layer/Au layer.

### Structure of Solder Resist Layer 23

The solder resist layer 23 is the outermost insulating layer (uppermost insulating layer) of the wiring substrate 20. The solder resist layer 23 is formed on the upper surface of the wiring structure 22. In the example illustrated in FIG. 1, the solder resist layer 23 is formed on the upper surface of the insulating layer 65 of the wiring structure 22. The material of the solder resist layer 23 may be, for example, an insulating resin including a photosensitive resin, such as a phenol resin or a polyimide resin, as a main component. The solder resist layer 23 may contain, for example, a filler such as silica or alumina.

The solder resist layer 23 is formed on the upper surface of the insulating layer 65 and exposes the first connection pads P1 and the second connection pads P2. For example, the solder resist layer 23 surrounds the first mounting region R1 and the second mounting region R2 in plan view. The solder resist layer 23 includes an open portion 23X that exposes the upper surface of the wiring structure 22 located in the first mounting region R1 and the second mounting region R2. The open portion 23X extends through the solder resist layer 23 in the thickness-wise direction. The open portion 23X exposes the upper surface of the insulating layer 63 and the first connection pads P1 located in the first mounting region R1. Further, the open portion 23X exposes the upper surface of the insulating layer 65 and the second connection pads P2 located in the second mounting region R2.

### Structures of First Electronic Component 71 and Second Electronic Component 72

The first electronic component 71 and the second electronic component 72 are mounted on the wiring substrate 20. The first electronic component 71 and the second electronic component 72 are mounted on the upper surface of the wiring structure 22. The first electronic component 71 and the second electronic component 72 may each be, for example, an active component such as a semiconductor chip, a transistor, or a diode, or a passive component such as a chip capacitor, a chip inductor, or a chip resistor. The first electronic component 71 and the second electronic component 72 may each be, for example, a silicon component or a ceramic component. The first electronic component 71 and the second electronic component 72 are, for example, different types of electronic components. In the example illustrated in FIG. 1, the first electronic component 71 is a semiconductor chip, and the second electronic component 72 is a chip capacitor. The semiconductor chip may be, for example, a logic chip such as a central processing unit (CPU) chip or a graphics processing unit (GPU) chip. Alternatively, the semiconductor chip may be, for example, a memory chip such as a dynamic random access memory (DRAM) chip, a static random access memory (SRAM) chip, or a flash memory chip.

The first electronic component 71 is flip-chip mounted on the first connection pads P1. For example, the first electronic component 71 is electrically connected to the first connection pads P1 by bumps 73. The bumps 73 are formed on a circuit formation surface (lower surface) of the first electronic component 71 and bonded to the first connection pads P1.

The second electronic component 72 is flip-chip mounted on the second connection pads P2. For example, the second electronic component 72 is electrically connected to the second connection pads P2 by bumps 74. The bumps 74 are formed on a lower surface of the second electronic component 72 and bonded to the second connection pads P2.

The bumps 73 and 74 may each be, for example, a gold bump or a solder bump. The material of a solder bump may be, for example, an alloy containing lead (Pb), an alloy of tin (Sn) and Au, an alloy of Sn and Cu, an alloy of Sn and silver (Ag), or an alloy of Sn, Ag, and Cu.

### Structure of Underfill Materials 81 and 82

The underfill material 81 fills a gap between the wiring substrate 20 and the first electronic component 71. The underfill material 81 fills a gap between the upper surface of the insulating layer 63 exposed from the open portion 65X and the lower surface of the first electronic component 71. The underfill material 81 covers the bumps 73 and the first connection pads P1. The underfill material 81 protects portions where the bumps 73 are connected to the first connection pads P1 from external stress and the like so as to improve the connection reliability. The underfill material 81 is disposed inside the open portion 65X. The material of the underfill material 81 may be, for example, an epoxy resin.

The underfill material 82 fills a gap between the wiring substrate 20 and the second electronic component 72. The underfill material 82 fills a gap between the upper surface of the insulating layer 65 and the lower surface of the second electronic component 72. The underfill material 82 covers the bumps 74 and the second connection pads P2. The underfill material 82 protects portions where the bumps 74 are connected to the second connection pads P2 from external stress and the like so as to improve the connection reliability. The underfill material 82 is separated from the underfill material 81. The material of the underfill material 82 may be, for example, an epoxy resin.

### Structure of External Connection Terminal 90

The external connection terminals 90 are formed on the external connection pads 54P of the wiring substrate 20. The external connection terminals 90 are, for example, connection terminals for electrical connection to pads arranged on a mounting board such as a motherboard (not illustrated). The external connection terminals 90 may be, for example, solders ball or lead pins. In an example, the external connection terminals 90 are solder balls.

### Method for Manufacturing Semiconductor Device 10

A method for manufacturing the semiconductor device 10 will now be described. To facilitate understanding, portions that will become elements of the semiconductor device 10 are given the same reference characters as the final elements.

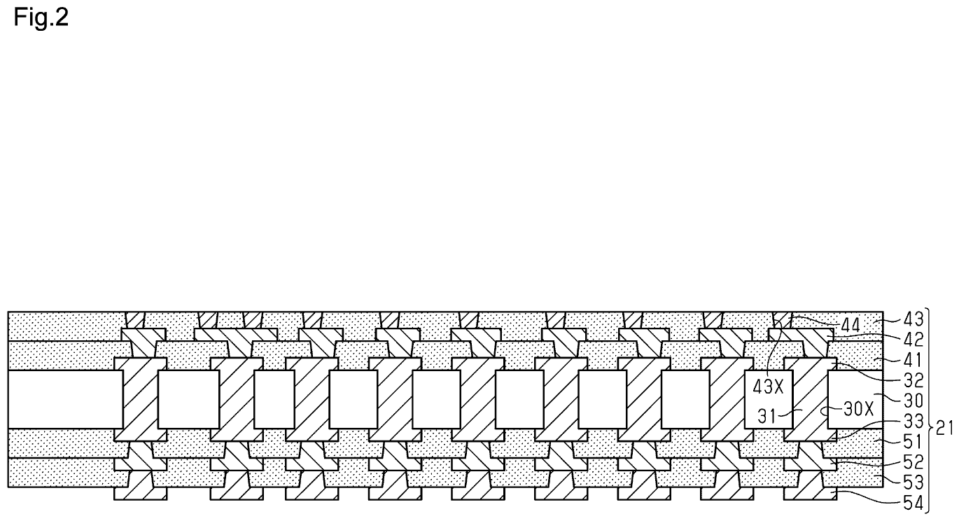

First, in the step illustrated in FIG. 2, a structural body is prepared by sequentially stacking the wiring layer 32, the insulating layer 41, the wiring layer 42, the insulating layer 43, and the via wiring 44 on the upper surface of the core substrate 30, and sequentially stacking the wiring layer 33, the insulating layer 51, the wiring layer 52, the insulating layer 53, and the wiring layer 54 on the lower surface of the core substrate 30. The structural body may be manufactured by a known manufacturing process. Thus, the process will not be described in detail.

Then, the upper surface of the insulating layer 43 and the upper end surface of the via wiring 44 are polished by a chemical mechanical polishing (CMP) process or the like. In this step, the upper surface of the insulating layer 43 becomes flush with the upper end surface of the via wiring 44. Further, the upper surface of the insulating layer 43 is smoothed by polishing the upper surface of the insulating layer 43. For example, the roughness Ra of the upper surface of the insulating layer 43 before polishing may be approximately 300 nm to 400 nm, and the roughness Ra of the upper surface of the insulating layer 43 after polishing may be approximately 15 nm to 40 nm. Accordingly, the upper surface of the insulating layer 43 is polished and smoothed. In this manner, the upper surface of the insulating layer 43 and the upper end surface of the via wiring 44 become polished surfaces. The above-described process manufactures the wiring structure 21.

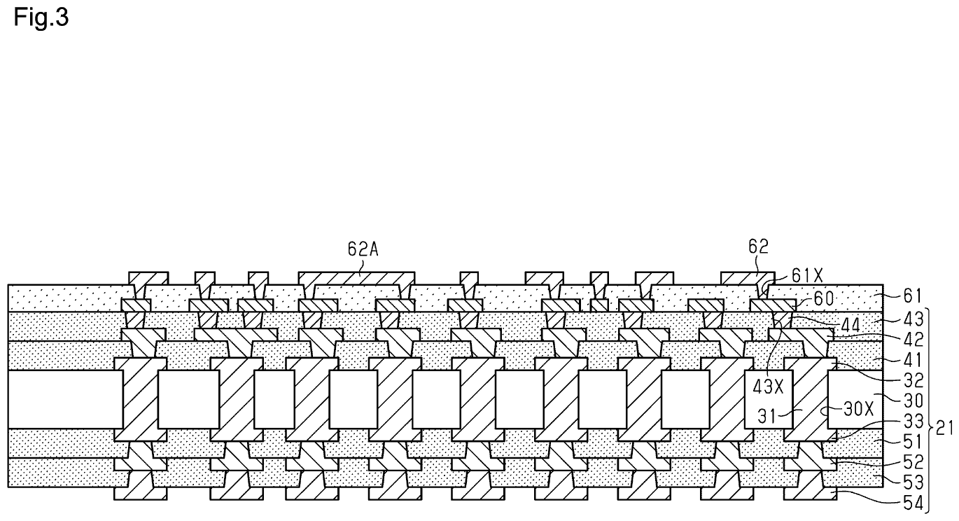

In the step illustrated in FIG. 3, the wiring layer 60 is formed on the upper surface of the insulating layer 43. The wiring layer 60 may be formed by any type of wiring forming process such as a subtractive process or a semi-additive process.

Subsequently, the insulating layer 61 including through holes 61X is formed on the upper surface of the insulating layer 43. The through holes 61X expose parts of an upper surface of the wiring layer 60. When using a resin film as the insulating layer 61, for example, the upper surface of the insulating layer 43 is laminated with a resin film through thermocompression bonding, and then the resin film is patterned by photolithography to form the insulating layer 61. The resin film may be, for example, a film of a photosensitive resin such as a phenol resin or a polyimide resin. When using a liquid or a paste of insulating resin as the insulating layer 61, for example, the upper surface of the insulating layer 43 is coated with a liquid or paste of insulating resin by spin coating or the like, and then the insulating resin is patterned by photolithography to form the insulating layer 61. The liquid or paste of insulating resin may be, for example, a liquid or paste of a photosensitive resin such as a phenol resin or a polyimide resin.

The upper surface of the insulating layer 61 formed from such a photosensitive resin may have a roughness Ra of, for example, approximately 2 nm to 10 nm. That is, the surface roughness of the upper surface of the insulating layer 61 is smaller than that of the upper surface of the insulating layer 43.

Next, the through holes 61X are filled with via wiring, and the wiring layer 62 is formed on the upper surface of the insulating layer 61. The wiring layer 62 is electrically connected to the wiring layer 60 by the via wiring. The via wiring and the wiring layer 62 may be formed by, for example, a semi-additive process. The wiring layer 62 includes the wiring 62A.

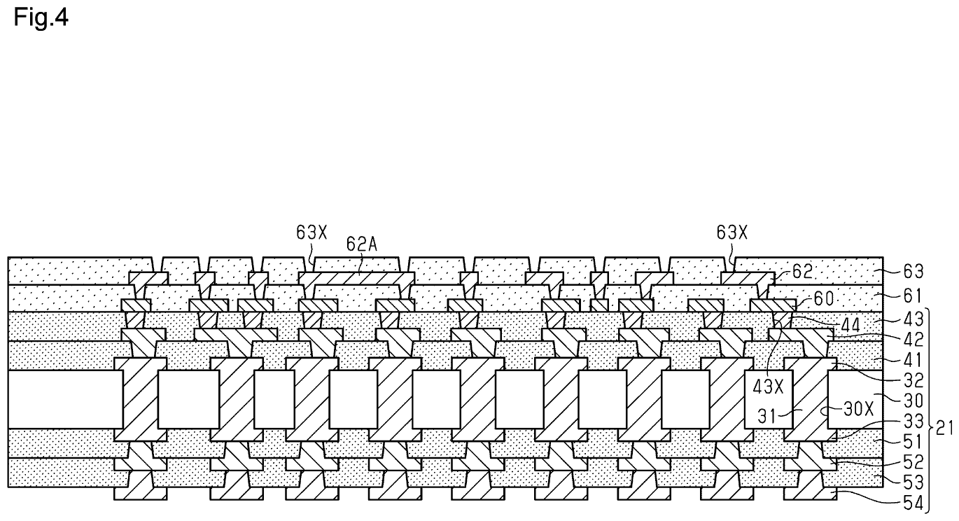

In the step illustrated in FIG. 4, the insulating layer 63 including the through holes 63X is formed on the upper surface of the insulating layer 61. The through holes 63X expose parts of the upper surface of the wiring layer 62. The insulating layer 63 may be formed, for example, in the same manner as the insulating layer 61.

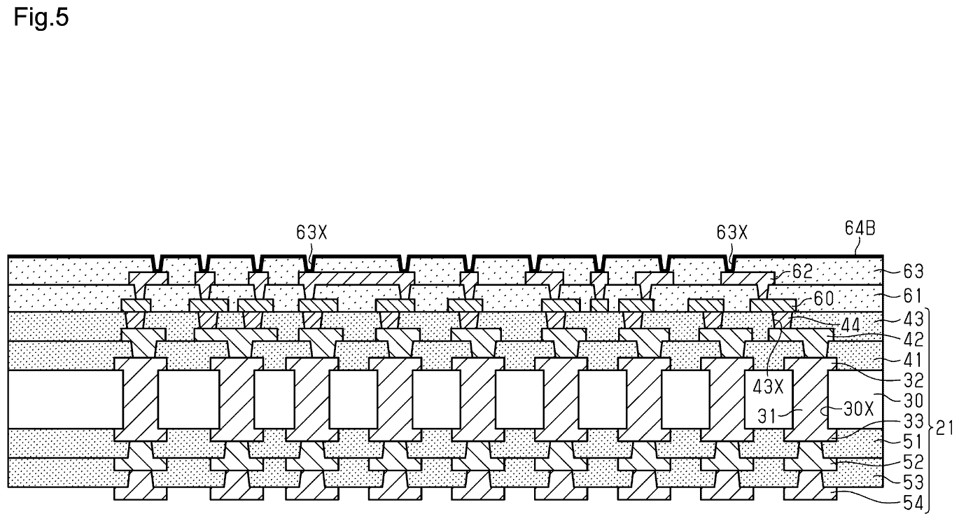

In the step illustrated in FIG. 5, a seed layer 64B is formed to cover the entire upper surface of the insulating layer 63 and the entire inner surface of each through hole 63X. The seed layer 64B continuously covers the entire upper surface of the insulating layer 63, the entire inner surface of each through hole 63X, and the entire upper surface of the wiring layer 62 exposed at the bottom of each through hole 63X. The seed layer 64B may be formed by, for example, sputtering or electroless plating. When forming the seed layer 64B by sputtering, for example, titanium (Ti) is first sputtered and deposited on the upper surface of the insulating layer 63 and the inner surface of the through holes 63X to form a Ti layer.

Subsequently, copper is sputtered and deposited on the Ti layer to form a Cu layer. This forms the seed layer 64B with a double-layered structure (Ti layer/Cu layer). In this case, for example, the Ti layer may have a thickness of approximately 20 nm to 50 nm, and the Cu layer may have a thickness of approximately 100 nm to 300 nm. The Ti layer formed in such a manner improves the adhesion between the insulating layer 63 and the seed layer 64B. The Ti layer may be changed to a TiN layer composed of titanium nitride (TiN), and the seed layer 64B may have a double-layered structure of the TiN layer and the Cu layer. Titanium or titanium nitride is a metal that is more resistant to corrosion than copper and has superior adhesion properties to the insulating layer 63 than copper. Alternatively, when forming the seed layer 64B by electroless plating, for example, electroless copper plating may be performed to form the seed layer 64B with a Cu layer (single-layered structure).

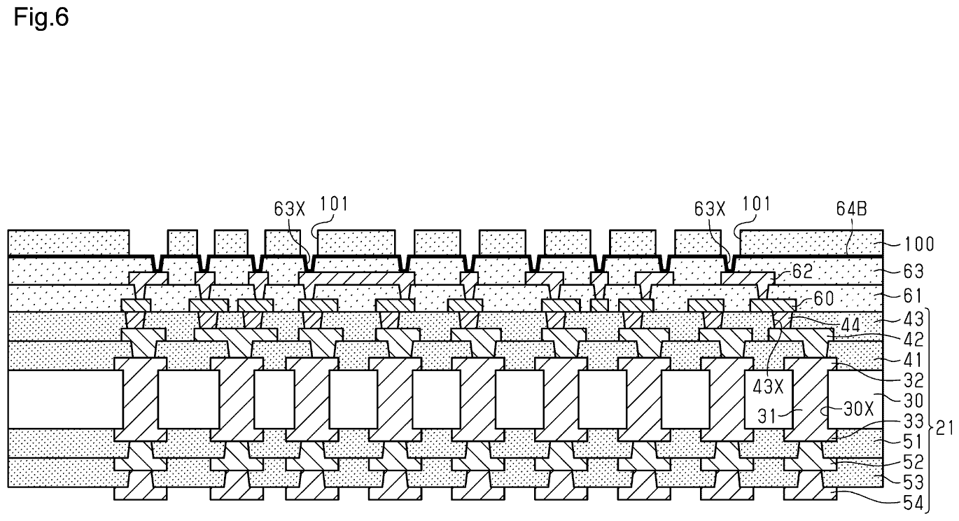

In the step illustrated in FIG. 6, a resist layer 100 including an opening pattern 101 is formed on the seed layer 64B. The opening pattern 101 exposes parts of the seed layer 64B located at portions where the wiring layer 64, illustrated in FIG. 1, is to be formed. The material of the resist layer 100 may be, for example, a material that is resistant to electrolytic plating performed in a subsequent step. The resist layer 100 may use, for example, a photosensitive dry film resist or a liquid photoresist. Examples of such a resist material include a novolac resin, an acrylic resin, or the like. When using a photosensitive dry film resist, for example, the upper surface of the seed layer 64B is laminated with a dry film through thermocompression bonding, and then the dry film is patterned by photolithography to form the resist layer 100 including the opening pattern 101. When using a liquid photoresist, the resist layer 100 may be formed through a similar process.

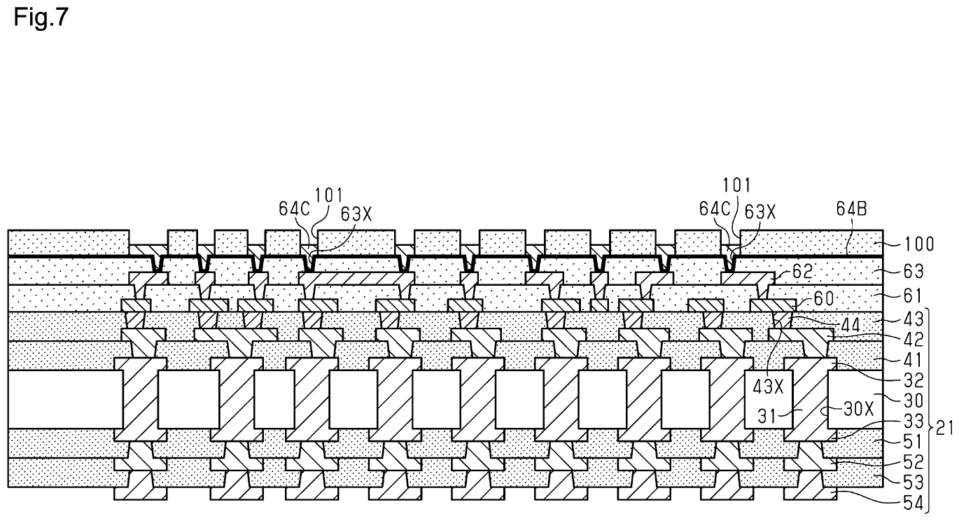

In the step illustrated in FIG. 7, electrolytic plating is performed on the seed layer 64B using the resist layer 100 as a plating mask and the seed layer 64B as a plating power feeding layer. That is, electrolytic plating (electrolytic Cu plating) is performed on the upper surface of the seed layer 64B exposed from the opening pattern 101 of the resist layer 100. This step forms a metal layer 64C, which fills the through holes 63X, in the opening pattern 101.

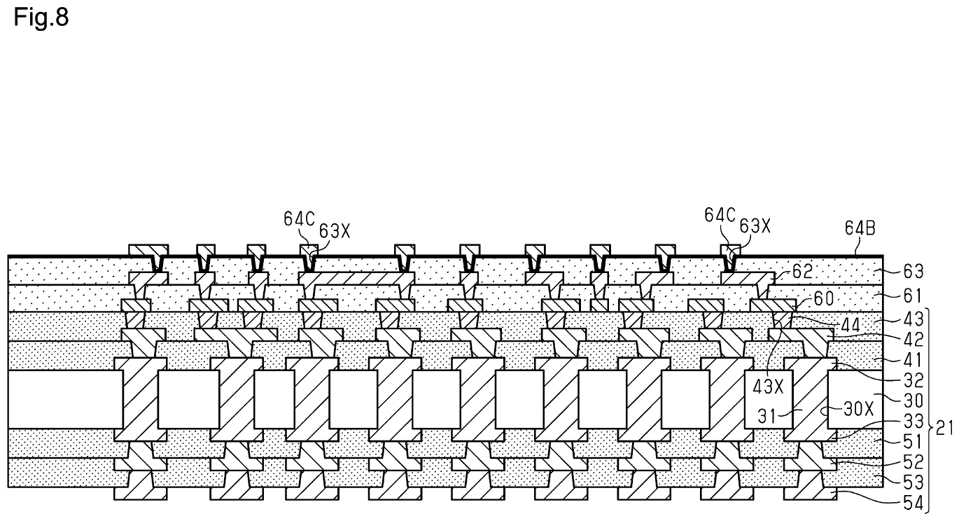

In the step illustrated in FIG. 8, the resist layer 100 of FIG. 7 is removed using an alkali stripping solution (e.g., organic amine stripping solution, caustic soda, acetone, or ethanol).

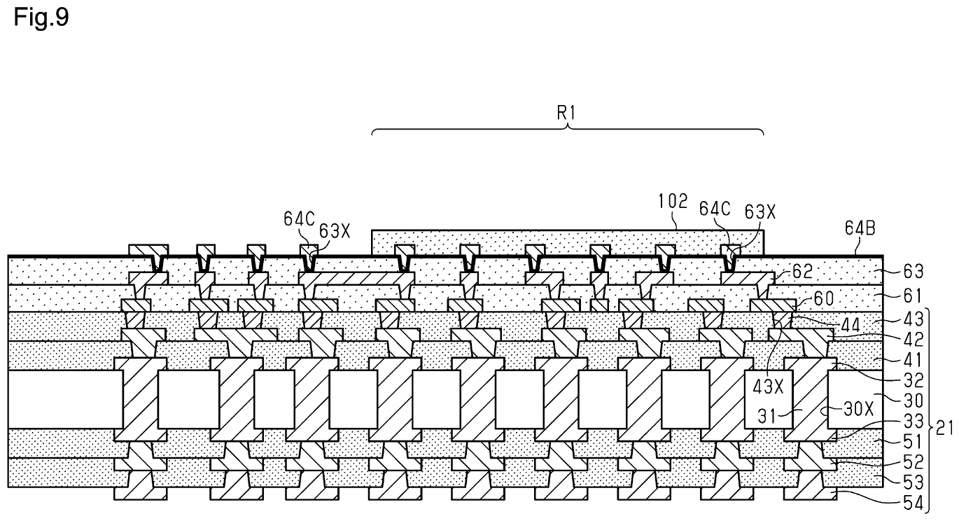

In the step illustrated in FIG. 9, a resist layer 102 is formed to cover the seed layer 64B and the metal layer 64C that are located in a portion corresponding to the first mounting region R1. The resist layer 102 covers the entire upper surface of the seed layer 64B in the first mounting region R1 and the entire upper surface and the entire side surface of the metal layer 64C in the first mounting region R1. In other words, the resist layer 102 exposes the seed layer 64B and the metal layer 64C that are located in portions outside the first mounting region R1. The material of the resist layer 102 may be, for example, a material that is resistant to etching performed in a subsequent step. The resist layer 102 may use, for example, a photosensitive dry film resist or a liquid photoresist. Examples of such a resist material include a novolac resin, an acrylic resin, or the like. When using a photosensitive dry film resist, for example, the upper surface of the seed layer 64B is laminated with a dry film through thermocompression bonding, and then the dry film is patterned by photolithography to form the resist layer 102. When using a liquid photoresist, the resist layer 102 may be formed through a similar process.

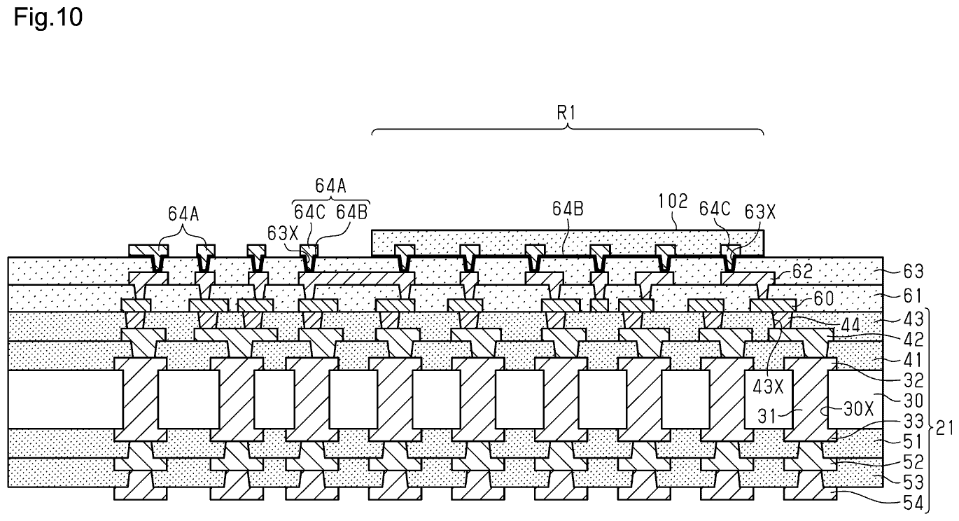

In the step illustrated in FIG. 10, etching is performed to remove unnecessary portions of the seed layer 64B using the metal layer 64C and the resist layer 102 as etching masks. This removes the seed layer 64B exposed from the metal layer 64C and the resist layer 102, that is, the unnecessary portions of the seed layer 64B located outside the first mounting region R1. This step forms the via wiring, which fills the through holes 63X, and the wiring patterns 64A in the outer peripheral region outside the first mounting region R1. Each wiring pattern 64A includes the seed layer 64B, which is formed on the upper surface of the insulating layer 63, and the metal layer 64C. In this manner, the via wiring and the wiring patterns 64A are formed by a semi-additive process. This step does not remove the seed layer 64B covered with the resist layer 102 in the first mounting region R1. In other words, in this step, etching is performed such that the seed layer 64B remains in the first mounting region R1.

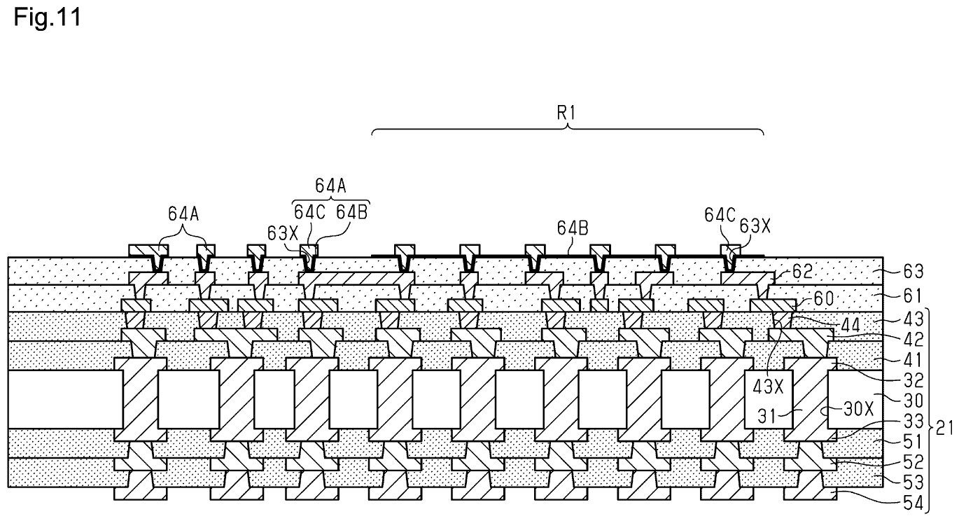

In the step illustrated in FIG. 11, the resist layer 102 in FIG. 10 is removed using an alkali stripping solution (e.g., organic amine stripping solution, caustic soda, acetone, or ethanol). This exposes the seed layer 64B located in the first mounting region R1. In this case, the upper surface of the insulating layer 63 in the first mounting region R1 is entirely covered with the seed layer 64B.

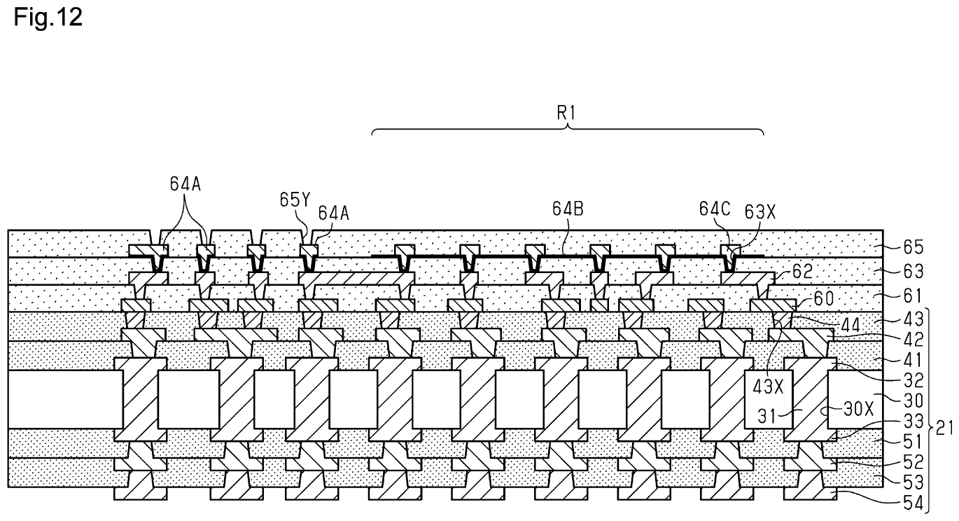

In the step illustrated in FIG. 12, the insulating layer 65 including through holes 65Y is formed on the upper surface of the insulating layer 63. The through holes 65Y expose parts of the upper surface of the wiring patterns 64A. In this case, the insulating layer 65 is formed to cover the seed layer 64B and the metal layer 64C located in the first mounting region R1. The insulating layer 65 may be formed, for example, in the same manner as the insulating layer 61.

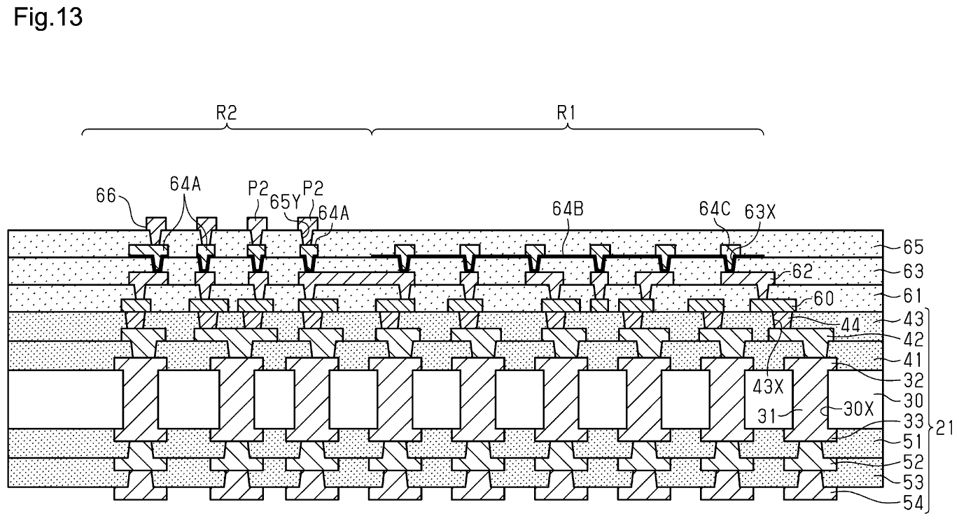

In the step illustrated in FIG. 13, the through holes 65Y are filled with via wiring, and the wiring layer 66 is formed. The wiring layer 66 is electrically connected to the wiring patterns 64A by the via wiring. The wiring layer 66 is formed on the upper surface of the insulating layer 65. The via wiring and the wiring layer 62 may be formed by, for example, a semi-additive process. This step forms the second connection pads P2 in the second mounting region R2.

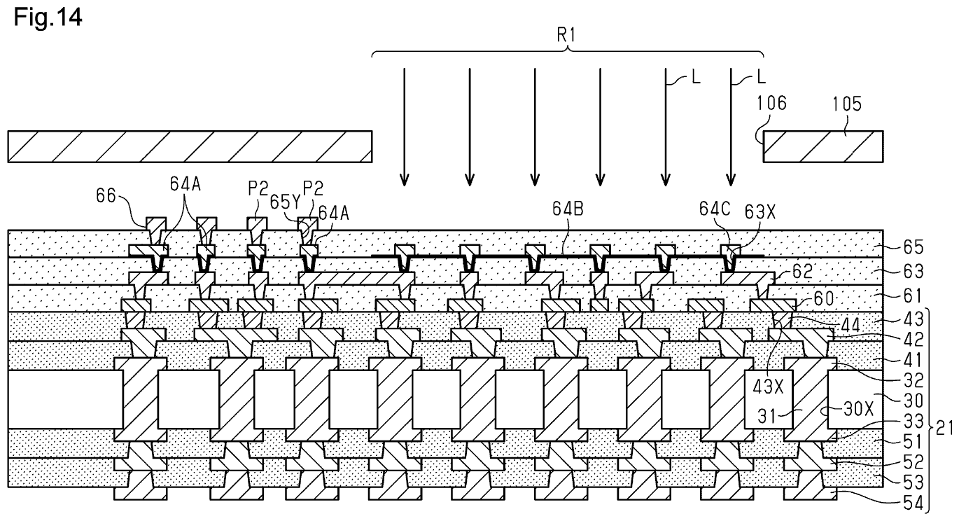

In the step illustrated in FIG. 14, a mask 105 including an open portion 106 is prepared, and the mask 105 is set above the insulating layer 65. The open portion 106 is formed in correspondence with the first mounting region R1. That is, the open portion 106 exposes the insulating layer 65 located in the first mounting region R1. Then, the upper surface of the insulating layer 65 is irradiated with a laser light L through the open portion 106 of the mask 105.

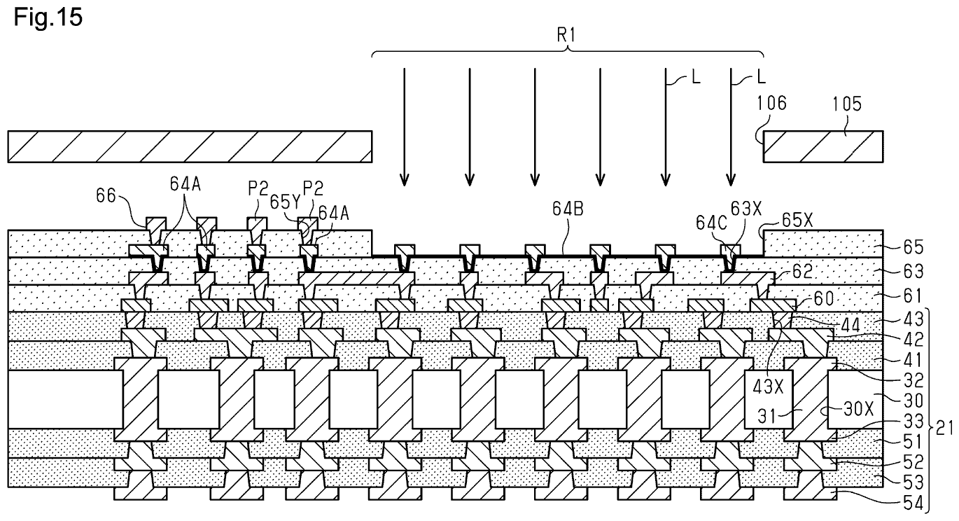

As illustrated in FIG. 15, the portion of the insulating layer 65 irradiated with the laser light L is removed. In other words, the insulating layer 65 is partially removed. This step forms the open portion 65X, which extends through the insulating layer 65 in the thickness-wise direction, in the first mounting region R1 that is exposed from the open portion 106 of the mask 105. The seed layer 64B formed on the upper surface of the insulating layer 65 is exposed from the open portion 65X. In this manner, the open portion 65X may be formed by laser drilling. The laser light L may be, for example, an excimer laser or a YAG laser. In this step, the seed layer 64B acts as a stopper layer for the laser drilling. Thus, the insulating layer 63 under the insulating layer 65 will not be thinned by, for example, excessive laser drilling.

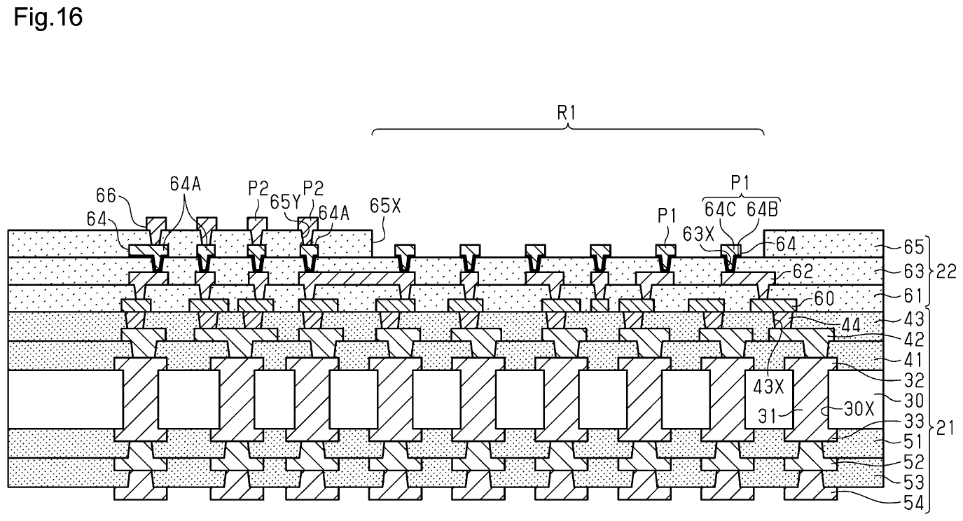

In the step illustrated in FIG. 16, etching is performed to remove unnecessary portions of the seed layer 64B in the first mounting region R1 using the metal layer 64C as an etching mask. This step forms the first connection pads P1, which include the seed layer 64B and the metal layer 64C, on the upper surface of the insulating layer 63 in the first mounting region R1. In this manner, the wiring layer 64 including the first connection pads P1 and the wiring patterns 64A is formed on the upper surface of the insulating layer 63.

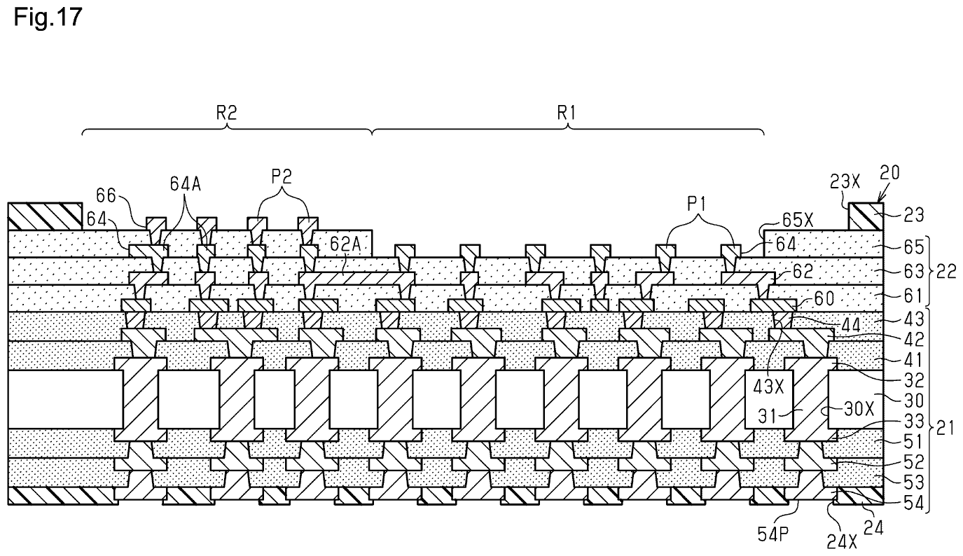

The above-described manufacturing process forms the wiring structure 22 on the upper surface of the wiring structure 21. In subsequent FIGS. 17 to 20, the seed layer 64B and the metal layer 64C in the wiring layer 64 will not be illustrated.

In the step illustrated in FIG. 17, the solder resist layer 23 including the open portion 23X is formed on the upper surface of the insulating layer 65 of the wiring structure 22. The open portion 23X exposes the first mounting region R1 and the second mounting region R2. Also, the solder resist layer 24 including the openings 24X is formed on the lower surface of the insulating layer 53 of the wiring structure 21. The openings 24X expose parts of the wiring layer 54 as the external connection pads 54P. The solder resist layers 23 and 24 may be formed by, for example, applying a photosensitive solder resist film or a liquid solder resist and patterning the resist into a desired shape.

A surface-processed layer may be formed, if necessary, on the first connection pads P1, the second connection pads P2, and the external connection pads 54P.

The above-described process manufactures the wiring substrate 20.

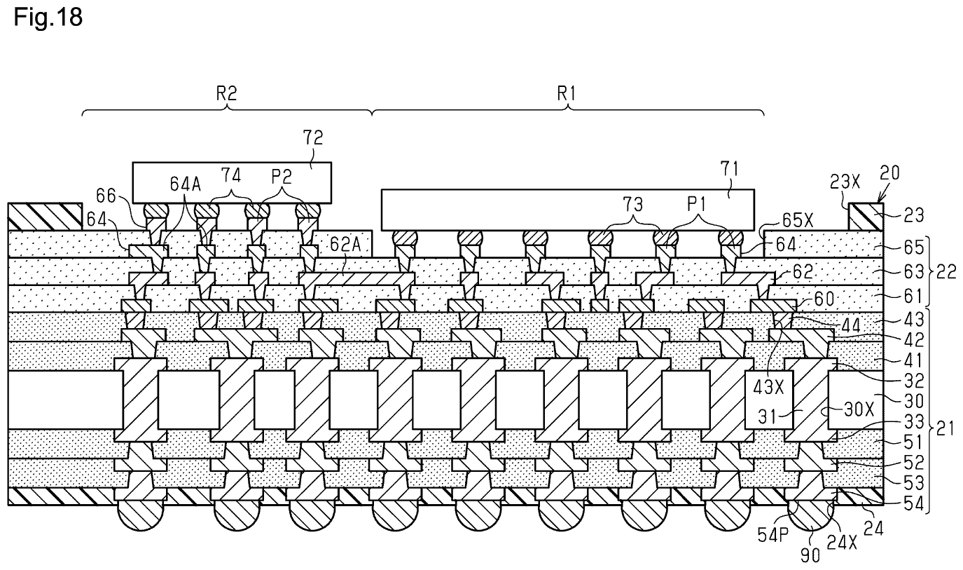

In the step illustrated in FIG. 18, the external connection terminals 90 are formed on the external connection pads 54P. For example, flux is applied to the external connection pads 54P. Then, the external connection terminals 90 (solder balls) are arranged and fixed by a reflow process performed at a temperature of approximately 240° C. to 260° C. Subsequently, the surface is cleaned to remove the flux.

Further, in the step illustrated in FIG. 18, the first electronic component 71 is mounted on the wiring substrate 20. The bumps 73 of the first electronic component 71 are, for example, flip-chip bonded to the first connection pads P1 of the wiring substrate 20. Furthermore, the second electronic component 72 is mounted on the wiring substrate 20. The bumps 74 of the second electronic component 72 are, for example, flip-chip bonded to the second connection pads P2 of the wiring substrate 20.

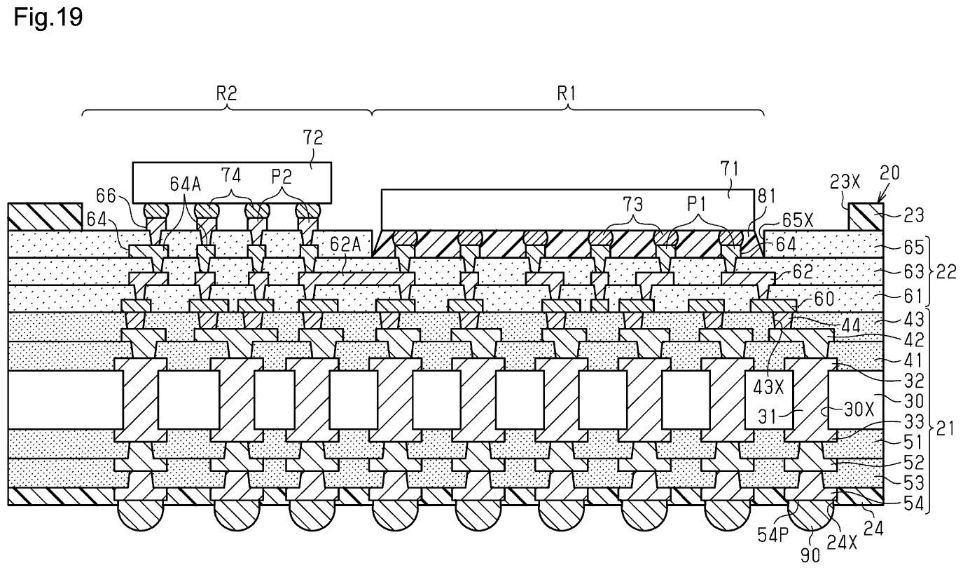

In the step illustrated in FIG. 19, the underfill material 81 is added to a gap between the flip-chip bonded first electronic component 71 and the wiring substrate 20, and then the underfill material 81 is cured. For example, a dispenser or the like is used to add the underfill material 81 to the gap between the lower surface of the first electronic component 71 and the upper surface of the insulating layer 63 exposed from the open portion 65X. Due to capillary action, the underfill material 81 spreads in the gap between the lower surface of the first electronic component 71 and the upper surface of the insulating layer 63 and also in a planar direction orthogonal to the stacking direction of the wiring substrate 20. In this case, the step is formed by the open portion 65X so that the inner wall surface of the open portion 65X does not allow the underfill material 81 to spread in the planar direction. In other words, the inner wall surface of the open portion 65X blocks spreading of the underfill material 81 in the planar direction. Thus, the underfill material 81 will not spread in the planar direction unnecessarily, and the amount of the underfill material 81 will remain sufficient in the gap between the first electronic component 71 and the insulating layer 63.

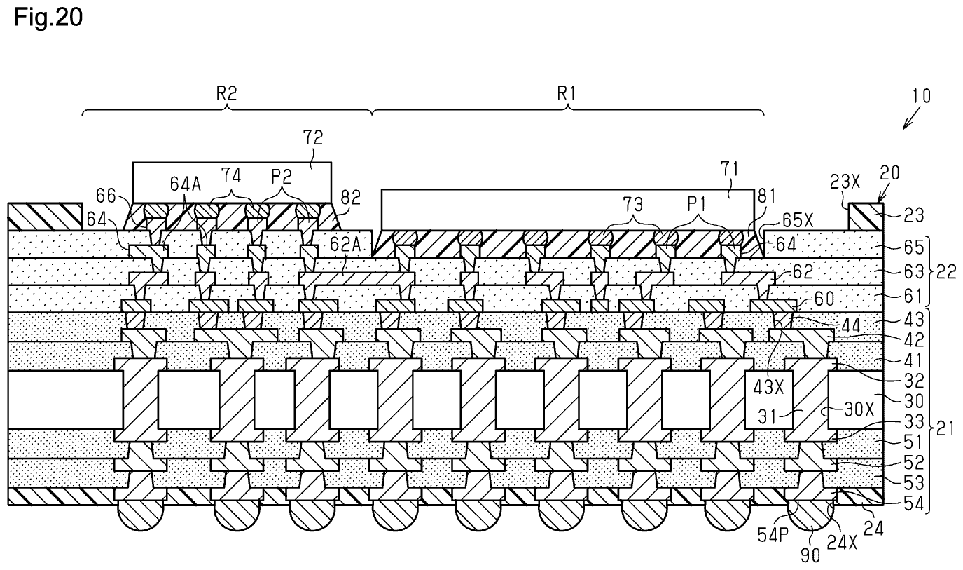

In the step illustrated in FIG. 20, the underfill material 82 is added to a gap between the flip-chip bonded second electronic component 72 and the wiring substrate 20, and then the underfill material 82 is cured. For example, a dispenser or the like is used to add the underfill material 82 to the gap between the lower surface of the second electronic component 72 and the upper surface of the insulating layer 65. Due to capillary action, the underfill material 82 spreads in the gap between the lower surface of the second electronic component 72 and the upper surface of the insulating layer 65 and also in the planar direction of the wiring substrate 20. In this case, the step is formed by the open portion 65X so that the gap between the second electronic component 72 and the insulating layer 65 is formed on a different plane from the gap between the first electronic component 71 and the insulating layer 63. This stops the underfill material 82 from spreading into the gap between the first electronic component 71 and the insulating layer 63. Thus, the underfill material 82 will not spread in the planar direction unnecessarily, and the amount of the underfill material 82 will remain sufficient in the gap between the second electronic component 72 and the insulating layer 65. The above-described process manufactures the semiconductor device 10 of the present embodiment.

The above embodiment has the following advantages.

(1) The wiring substrate 20 includes the wiring layer 62, the insulating layer 63, and the wiring layer 64. The insulating layer 63 covers the wiring layer 62. The wiring layer 64 is formed on the upper surface of the insulating layer 63 and is electrically connected to the wiring layer 62. The wiring substrate 20 includes the insulating layer 65 and the wiring layer 66. The insulating layer 65 is formed on the upper surface of the insulating layer 63. The wiring layer 66 is formed on the upper surface of the insulating layer 65 and is electrically connected to the wiring layer 64. The wiring layer 64 includes the first connection pads P1 connected to the first electronic component 71, and the wiring patterns 64A electrically connected to the wiring layer 66. The insulating layer 65 includes the open portion 65X extending through the insulating layer 65 in the thickness-wise direction and exposing the first connection pads P1 and part of the upper surface of the insulating layer 63. The wiring layer 66 includes the second connection pads P2 connected to the second electronic component 72, which differs from the first electronic component 71. The wiring layer 62 includes the wiring 62A that electrically connects the first connection pads P1 and the second connection pads P2.

With this configuration, the first connection pads P1 are formed on the upper surface of the insulating layer 63 that is exposed from the open portion 65X, and the second connection pads P2 are formed on the upper surface of the insulating layer 65 that is arranged on the upper surface of the insulating layer 63. Thus, the first connection pads P1 configured to be connected to the first electronic component 71 are located on a different plane from the second connection pads P2 configured to be connected to the second electronic component 72. Accordingly, when the first electronic component 71 and the second electronic component 72 are mounted on the wiring substrate 20, the gap between the first electronic component 71 and the insulating layer 63 is formed on a different plane from the gap between the second electronic component 72 and the insulating layer 65. Therefore, the underfill material 81 added to the gap between the first electronic component 71 and the insulating layer 63 will not spread into the gap between the second electronic component 72 and the insulating layer 65. Further, the underfill material 82 added to the gap between the second electronic component 72 and the insulating layer 65 will not spread into the gap between the first electronic component 71 and the insulating layer 63. In this manner, the underfill materials 81 and 82 will not spread in the planar direction unnecessarily and the amounts of the underfill materials 81 and 82 will remain sufficient. This adjusts the amounts of the underfill materials 81 and 82 so that the underfill materials 81 and 82 evenly fill the gap between the first electronic component 71 and the insulating layer 63 and the gap between the second electronic component 72 and the insulating layer 65. As a result, the connection reliability is maintained at portions where the bumps 73 of the first electronic component 71 are connected to the first connection pads P1 and portions where the bumps 74 of the second electronic component 72 are connected to the second connection pads P2.

(2) The open portion 65X exposes the entire upper surface and the entire side surface of each first connection pad P1. Thus, when mounting the first electronic component 71 on the first connection pad P1, the bumps 73 of the first electronic component 71 may be bonded to the upper surface and the side surface of the first connection pads P1. This increases the bonding area between the bumps 73 and the first connection pads P1 to be greater than when the bumps 73 are bonded to only the upper surface of the first connection pads P1, thereby improving the connection reliability between the bumps 73 and the first connection pads P1.

(3) The upper surface of the insulating layer 63 exposed from the open portion 65X is flat. Thus, when filling the gap between the first electronic component 71 and the insulating layer 63 with the underfill material 81, the underfill material 81 will have a higher filling capability than when the upper surface of the insulating layer 63 is uneven. As a result, the underfill material 81 evenly fills the gap between the first electronic component 71 and the insulating layer 63.

(4) In the step of forming the wiring layer 64, the seed layer 64B located in the first mounting region R1 is left on the upper surface of the insulating layer 63, and then the insulating layer 65 is formed on the upper surface of the insulating layer 63 to cover the remaining seed layer 64B. Further, the open portion 65X is formed in the insulating layer 65 by removing part of the insulating layer 65 using the remaining seed layer 64B as a stopper layer. When removing the part of the insulating layer 65, the seed layer 64B acts as, for example, a stopper layer for laser drilling so that the insulating layer 63 under the insulating layer 65 will not be thinned by excessive laser drilling. This avoids formation of irregularities on the upper surface of the insulating layer 63 and maintains the upper surface of the insulating layer 63 exposed from the open portion 65X as flat. As a result, when filling the gap between the first electronic component 71 and the insulating layer 63 with the underfill material 81, the filling capability of the underfill material 81 will remain sufficient.

### Other Embodiments

The above embodiment may be modified as described below. The above embodiment and the following modifications may be combined as long as the combined modifications remain technically consistent with each other.

In the above embodiment, the open portion 65X is formed in the insulating layer 65 so that a single step is formed in the upper surface of the wiring structure 22. Instead, for example, two or more steps may be arranged in the upper surface of the wiring structure 22.

In the above embodiment, a single open portion 65X is formed in the insulating layer 65. Instead, for example, multiple open portions 65X may be formed in the insulating layer 65.

In the above embodiment, a single first electronic component 71 is mounted on the first connection pads P1 exposed from the open portion 65X. Instead, for example, multiple electronic components may be mounted on the first connection pads P1 exposed from the open portion 65X.

In the above embodiment, a single second electronic component 72 is mounted on the second connection pads P2 formed on the upper surface of the insulating layer 65. Instead, for example, multiple electronic components may be mounted on the second connection pads P2 formed on the upper surface of the insulating layer 65.

The number of wiring layers, the wiring layout, or the like of the wiring structure 21 of the above embodiment may be modified in any manner. Further, the number of insulating layers of the wiring structure 21 may be modified in any manner.

In the above embodiment, the wiring layers 32 and 33 are located above and below the core substrate 30 and are electrically connected to each other by the through-electrodes 31 in the through holes 30X of the core substrate 30. Alternatively, the wiring layers 32 and 33 may be electrically connected to each other by, for example, a through-hole plating layer formed on the inner wall of each through hole 30X. In this case, the through holes 30X may also be filled with resin that covers the through-hole plating layer.

The wiring structure 21 may be omitted.

The number of wiring layers, the wiring layout, or the like of the wiring structure 22 of the above embodiment may be modified in any manner. Further, the number of insulating layers of the wiring structure 22 may be modified in any manner.

In the above embodiment, the solder resist layers 23 and 24 are described as examples of protective insulating layers that correspond to the outermost insulating layers of the wiring substrate 20. However, a protective insulating layer may be formed from any type of photosensitive insulating resin.

In the above embodiment, the solder resist layer 23 may be formed on the upper surface of the insulating layer 63 that is exposed from the open portion 65X.

The solder resist layers 23 and 24 of the above embodiment may be omitted.

In the manufacturing method of the above embodiment, the open portion 65X is formed by laser drilling. However, the open portion 65X may be formed by a different process. The open portion 65X may be formed by removing part of the insulating layer 65 by, for example, plasma treatment or a blasting process.

In the manufacturing method of the above embodiment, the external connection terminals 90 may be formed at any time. The external connection terminals 90 may be formed, for example, after the first electronic component 71 and the second electronic component 72 are mounted on the wiring substrate 20.

### CLAUSES

This disclosure further encompasses the following embodiments.

1. A method for manufacturing a wiring substrate, the method including:
forming a first insulating layer that covers a first wiring layer;
forming a second wiring layer on an upper surface of the first insulating layer, the second wiring layer including a first connection pad and a wiring pattern that are electrically connected to the first wiring layer;
forming a second insulating layer on the upper surface of the first insulating layer, the second insulating layer covering the second wiring layer;
forming a third wiring layer on an upper surface of the second insulating layer, the third wiring layer including a second connection pad electrically connected to the wiring pattern; and
forming an open portion that exposes the first connection pad of the second wiring layer by removing part of the second insulating layer,
in which the open portion extends through the second insulating layer in a thickness-wise direction and exposes part of the upper surface of the first insulating layer.

2. The method according to clause 1, in which:
the forming the first insulating layer includes forming a first through hole that extends through the first insulating layer and exposes part of an upper surface of the first wiring layer;
the forming the second wiring layer includes
forming a seed layer that entirely covers the upper surface of the first insulating layer and an inner surface of the first through hole,
forming a first resist layer on the seed layer, the first resist layer including an opening pattern,
forming a metal layer on the seed layer that is exposed from the opening pattern by electrolytic plating using the first resist layer as a plating mask,
removing the first resist layer,
forming a second resist layer on the seed layer, the second resist layer covering the metal layer and the seed layer in a region for forming the first connection pad,
removing the seed layer exposed from the metal layer and the second resist layer while leaving part of the seed layer covered with the second resist layer as a remaining part, and
removing the second resist layer;
the second insulating layer is formed to cover the remaining part of the seed layer; and
the open portion is formed by removing part of the second insulating layer using the remaining part of the seed layer as a stopper layer.

3. The method according to clause 2, in which the open portion is formed by laser drilling using the remaining part of the seed layer as the stopper layer.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate, comprising:
a first wiring layer;
a first insulating layer that covers the first wiring layer;
a second wiring layer formed on an upper surface of the first insulating layer and electrically connected to the first wiring layer;
a second insulating layer formed on the upper surface of the first insulating layer; and
a third wiring layer formed on an upper surface of the second insulating layer and electrically connected to the second wiring layer, wherein:
the second wiring layer includes
a first connection pad configured to be connected to a first electronic component, and
a wiring pattern electrically connected to the third wiring layer;
the second insulating layer includes an open portion extending through the second insulating layer in a thickness-wise direction, the open portion exposing the first connection pad and part of the upper surface of the first insulating layer;
the third wiring layer includes a second connection pad configured to be connected to a second electronic component that differs from the first electronic component; and
the first wiring layer includes wiring that electrically connects the first connection pad and the second connection pad.

2. The wiring substrate according to claim 1, wherein the open portion exposes an entire upper surface and an entire side surface of the first connection pad.

3. The wiring substrate according to claim 1, further comprising:
a step formed by the upper surface of the second insulating layer, an inner wall surface of the open portion, and the upper surface of the first insulating layer that is exposed from the open portion,
wherein the upper surface of the first insulating layer exposed from the open portion is flat.

4. The wiring substrate according to claim 1, wherein:
the open portion has a planar shape that corresponds to a planar shape of a first mounting region in which the first electronic component is mounted;
the first connection pad is one of first connection pads arranged in the first mounting region; and
the open portion exposes all of the first connection pads and entirely exposes the upper surface of the first insulating layer in the first mounting region.

5. The wiring substrate according to claim 1, wherein:
the first connection pad for the first electronic component and the wiring pattern are coplanar with each other on the upper surface of the first insulating layer;
the open portion is a recess that is recessed from the upper surface of the second insulating layer and has a bottom surface defined by the upper surface of the first insulating layer so that the recess exposes the first connection pad while covering the wiring pattern with the second insulating layer; and
the second connection pad for the second electronic component is located on the upper surface of the second insulating layer and electrically connected to the wiring pattern by via wiring that extends through the second insulating layer.

6. The wiring substrate according to claim 1, further comprising:
a first wiring structure including a third insulating layer and via wiring, the via wiring filling a through hole extending through the third insulating layer in the thickness-wise direction, the via wiring including an upper end surface exposed from the third insulating layer; and
a second wiring structure formed on an upper surface of the third insulating layer, wherein:
the second wiring structure includes the first wiring layer, the first insulating layer, the second wiring layer, the second insulating layer, and the third wiring layer; and
the second wiring structure has a wiring density that is higher than a wiring density of the first wiring structure.

7. A semiconductor device, comprising:
the wiring substrate according to claim 1;
the first electronic component flip-chip mounted on the first connection pad;
the second electronic component flip-chip mounted on the second connection pad;
a first underfill material formed between the first electronic component and the first insulating layer; and
a second underfill material formed between the second electronic component and the second insulating layer.
